(19) United States
(12) Patent Application Publication
(10) Pub. No.: US 2017/0182737 A1
(43) Pub. Date: Jun. 29, 2017

(54) OPAQUE-PLASTIC FILM ON A FIBER SURFACE

(71) Applicant: HEWLETT-PACKARD DEVELOPMENT COMPANY, L.P., HOUSTON, TX (US)

(72) Inventors: KUAN-TING WU, TAIPEI CITY (TW); YAO-WEN FAN, TAIPEI CITY (TW); CHENG-FENG LIAO, TAIPEI CITY (TW)

(21) Appl. No.: 15/309,546

(22) PCT Filed: Jul. 31, 2014
(86) PCT No.: PCT/US2014/049011

§ 371 Date: Nov. 8, 2016

(51) Int. Cl. B32B 5/08; B32B 27/20; B32B 27/30; B32B 37/06; B32B 27/36; B32B 37/14; C23C 14/22; B32B 27/12; B32B 27/34

(52) U.S. Cl. CPC B32B 5/08; B32B 27/12; B32B 27/20; B32B 27/302; B32B 27/34; B32B 27/365; B32B 37/14; C23C 14/22; B32B 37/06; B32B 2260/021; B32B 2262/101; B32B 2262/106; B32B 2264/102; B32B 2264/108; B32B 2307/41; B32B 2255/02

(57) ABSTRACT

An example composite material having a substrate formed from carbon and/or glass fibers, and an opaque-plastic film positioned onto the substrate, where the opaque-plastic film has a surface roughness of between 0.001 nm and 1 mm.

### BACKGROUND

Some materials may comprise carbon and/or glass fibers. Such fiber-based materials may be used for automotive components, bicycle frames, fishing rods, protective cases for computers and smart phones, satellites, the oil and gas industry, and numerous other applications.

### BRIEF DESCRIPTION OF THE DRAWINGS

For a detailed description of various examples, reference will now be made to the accompanying drawings in which:

FIG. 1A illustrates a composite material which comprises a fiber (substrate) between opaque-plastic films in accordance with various examples;

FIG. 1B illustrates a composite material comprising a fiber, an opaque-plastic films, and physical vapor deposition (PVD) coatings in accordance with various examples;

FIG. 2 shows an illustration of a composite material which comprises a multilayer substrate comprised of layers of carbon and/or glass fibers alternatively layered with a plastic film, with a plastic film on one side of the composite material and an opaque-plastic film on the other side, in accordance with various examples;

FIG. 3 shows an illustration of a composite material, which comprises a multilayer substrate comprised of layers of carbon and/or glass fibers alternatively layered with a plastic film, an opaque-plastic film base layer, and an opaque-plastic film surface top layer in accordance with various examples;

FIG. 4 shows an illustration of a composite material, which comprises a multilayer substrate comprised of layers of carbon fibers, an opaque-plastic film base layer, and an opaque-plastic film top layer in accordance with various examples;

FIG. 5 shows an illustration of a composite material, which comprises a multilayer substrate comprised of a number of consecutive layers of fiber, a plastic film layer, and a number of consecutive layers of fiber; an opaque-plastic film, base layer; and opaque-plastic films in accordance with various examples; and

FIG. 6 and FIG. 7 show flow charts that illustrate methods of making composite materials such as those illustrated in FIGS. 1-5, and in accordance with various examples.

### DETAILED DESCRIPTION

In the following description, reference is made to the accompanying drawings, which form a part hereof, and in which is shown by way of illustration an example of the disclosed implementations. It is to be understood that other implementations may be utilized and structural changes may be made without departing from the scope of the present disclosure.

Many materials comprise carbon and/or glass fibers. Such materials, however, may exhibit surface roughness, and accordingly, the fiber is prone to texture deformation of the fiber surface due to the application of stress during compression molding. Such materials therefore may be prone to surface defects, and may not be suitable surfaces for painting or for other functional coatings. In accordance with the disclosed examples, an opaque-plastic film is positioned on the external surface of a fiber. The opaque-plastic film is smoother than the fiber and provides a more suitable surface for the application of functional coatings.

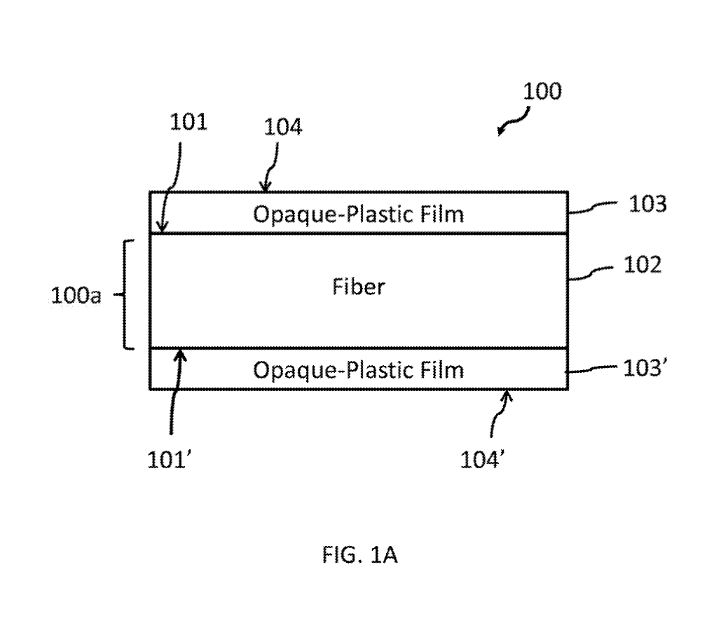

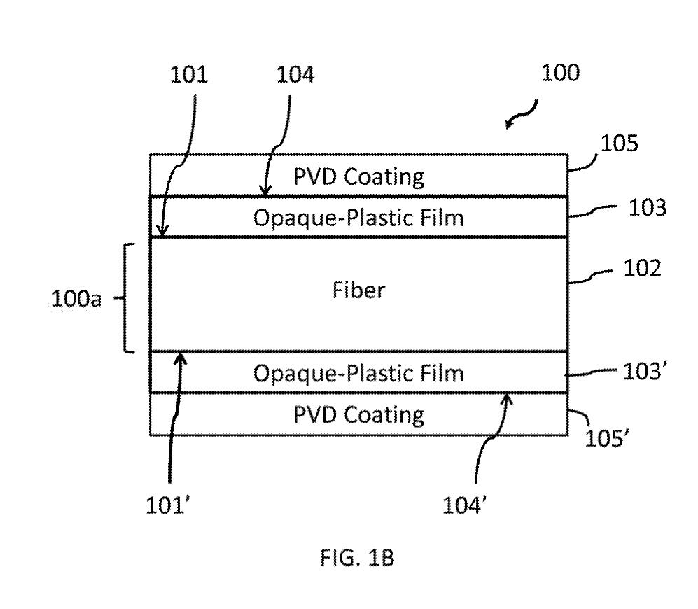

Various examples of composite materials are described herein. FIG. 1A, for example, shows a composite material 100 that includes a substrate 100a. In some implementations, the substrate 100a comprises a fiber 102 having various surfaces such as a first fiber surface 101 and an opposing second fiber surface 101′. The fiber 102 may comprise a carbon fiber, a glass fiber, or a combination of carbon and glass fibers.

The composite material also comprises opaque-plastic films 103 and 103′ which are positioned adjacent the first and second fiber surfaces 101 and 101′, respectively, as shown. The opaque-plastic film 103 has a first opaque plastic-film surface 104 which is opposite the first fiber surface 101 of the first fiber 102. Similarly, the opaque-plastic film 103′ also has a second opaque plastic-film surface 104′ which is opposite the first fiber surface 101′ of the first fiber 102.

The opaque-plastic films described herein (such as films 103 and 103′ in FIG. 1, but other opaque-plastic films in the other disclosed examples as well) may comprise a transmittance of incident light in the range of: 1 to 99%; 5 to 95%, 10% to 90%; 15% to 90%; 20% to 90%; 25% to 90%; 30% to 90%; 35% to 90%, 40% to 90%; 45% to 90%; 50% to 90%; 55% to 90%; 60% to 90%; 65% to 90%; 70% to 90%, 75% to 90%, and 85% to 90%. In another example the opaque-plastic films may have an opacity of: 10% to 90%; 15% to 90%; 20% and 90% and between 20% and 85%. The opacity of the opaque-plastic films 103 and 103′ may be the same or different,

The first and second opaque plastic-film surfaces 104 and 104′ (external surfaces of the opaque-plastic films 103, 103′) are smoother than the first and second fiber surfaces 101 and 101′. In one example, the surface roughness of the first and second opaque plastic-film surfaces 104 and 104′ may be in the range of 0.1 mm to 1 mm, 0.01 mm to 0.1 mm, and 0.001 mm to 0.01 mm. In one example, the surface roughness of the first opaque plastic-film surface 104 may be between 0.001 nm and 1 mm. The surface roughness of the two opaque plastic-film surfaces 104 and 104′ may be the same or different.

In some examples the first fiber surface 101 has a greater surface roughness than the opaque plastic-film surface 104, and similarly the second fiber surface 101′ has a greater surface roughness than the surface roughness of second plastic-film surface 104′, in some examples the ratio of the surface roughness of the first fiber surface (for example 101) to the first opaque plastic-film surface (for example 104) is 99:1 to 1:99; 9:1 to 1:9; 8:2 to 2:8; 7:3 to 3:7; and 6:4 to 4:6.

Further, the opaque-plastic films described herein may comprise polymers selected from: acrylonitrile butadiene styrene (ABS), polycarbonate (PC), polybutylene (PB), poly vinylidene fluoride (PVDF), polyacrylate, polyether ether ketone (PEEK), PC/ABS, polyamide (PA6 or PA56), PPS, or copolymers thereof. The ratios of such polymers may be selected to impart surface roughness, opacity, transmittance and flexural moduli in the ranges herein described, and further comprises fillers, such as carbon black, titanium dioxide, clay, mica, talc, barium sulfate, calcium carbonate, synthetic pigment, metallic powder, dye, aluminum oxide, grapheme, graphite, organic or inorganic powders, plastic beads and combinations thereof. Such fillers comprise less than 30 wt % of the opaque-plastic film, less than 20 wt % and less than 10 wt % of the opaque plastic film.

An example of an opaque-plastic film may comprise PC and ABS in a ratio 60% PC to 40% ABS wherein the surface roughness is 0.06 mm, flexural modulus is 4.5 Gpa and transmittance is 65%.

An opaque-plastic film that is applied to the rough surfaces of the substrate (e.g., the fiber 102 as described above) provides an external opaque plastic-film surface that has a low surface roughness and is therefore generally smooth, essentially defect free surface suitable for further processing. For example, the external surface 104, 104′ of the opaque-plastic films 103, 103′ may be visibly smooth to the human eye, and does not comprise non-uniform protrusions of substrate fibers. The use of such an opaque-plastic film also imparts a greater flexural modulus to the material. Such a flexural modulus may be in the range of 0.5 Gpa to 12 Gpa; 1 Gpa to 8 Gpa; 2.5 Gpa to 7 Gpa; 3 Gpa to 6.5 Gpa and 4 Gpa to 6 Gpa, and therefore provide a range of stiffness (or flexibility) for the composite materials described herein.

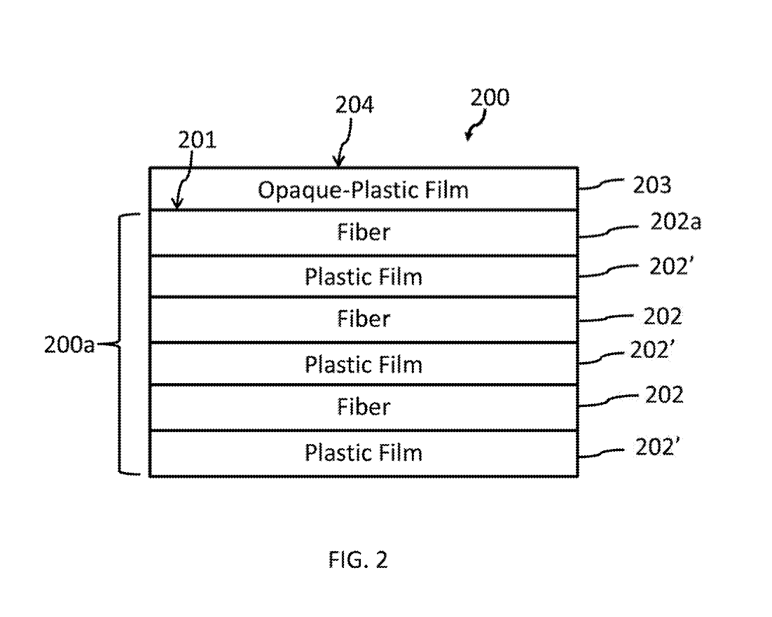

In some examples, the substrate may be multilayered, wherein the substrate comprises glass fibers, carbon fibers, or combinations thereof, and may further comprise plastic layers. The fiber 102 may also be impregnated with polymers such as Polycarbonate/Acrylonitrile Butadiene Styrene (PC-ABS), thereby imparting additional strength to the composite material substrate. As described above, the fiber may comprise a plastic film (as illustrated for example in FIG. 2), the plastic film 102′ may comprise thermosetting or thermoplastic plastics, and the use of a plastic film within the substrate of the composite material imparts a greater stiffness to the material while maintaining low density. The plastic film may comprise Acrylonitrile butadiene styrene (ABS), polycarbonate, polybutylene (PB), poly vinylidene fluoride (PVDF), polyacrylate, Polyether ether ketone (PEEK), PC/ABS, polyamide (PA6 or PA66), PPS; or copolymers thereof. The opaque-plastic film 103, comprises Acrylonitrile butadiene styrene (ABS), polycarbonate, polybutylene (PB), poly vinylidene fluoride (PVDF), polyacrylate, Polyether ether ketone (PEEK), PC/ABS, polyamide (PA6 or PA66), PPS; or copolymers thereof, wherein the ratio's of such polymers are selected to impart flexural moduli and/or stiffness in the ranges herein described, and may further comprises fillers, such as carbon black, titanium dioxide, clay, mica, talc, barium sulfate, calcium carbonate, synthetic pigment, metallic powder, dye, aluminum oxide, graphene, graphite, organic or inorganic powders, plastic beads and combinations thereof. Such fillers comprise less than 30 wt % of the plastic film, less than 20 wt %, and less than 10 wt % of the plastic film.

The glass fibers, carbon fibers, plastics (plastic film, and opaque-plastic film layers) or combinations thereof may be arranged so that each material is stacked in a lay-up structure comprised of discrete layers. Each material in the lay-up structure may be arranged to impart strength to the composite material. In some examples the fibers comprising the lay-up structure may be woven, and in other examples the lay-up structure may comprise uni-directional fibers.

The lay-up structure may be laminated and a physical vapor deposition (PVD) coating applied. Further functional coatings then may be applied to the laminated coating. FIG. 1B shows an example, similar to that of FIG. 1A, but also including PVD coatings 105 and 105′.

The opaque plastic-films herein described provide a thin, smooth and opaque surface onto which additional layers may be placed (such as PVD coatings). The opaqueness of the opaque plastic-film firstly hides the imperfections of the fiber (such as 102) to the naked eye that would be visible if a non opaque film was used, and secondly the opaqueness of the film results in a reduced thickness of PVD coat or paint coat for that would be needed to cover an opaque plastic-film surface as opposed to a non opaque plastic film surface which would require a greater thickness of PVD or paint to cover the underlying fiber and obscure the rough surface beneath.

FIG. 2 illustrates another example of a composite material 200. The composite material 200 comprises a substrate 200a, that is comprised of at least one fiber 202, and at least one plastic film 202′. The combination of fiber and plastic film form a multilayered substrate. In the example of FIG. 2, the substrate comprises multiple alternating layers of fiber 202 and plastic film 202′. The uppermost fiber 202a in FIG. 2 comprises a first fiber surface 201, onto which an opaque-plastic film 203 is positioned. The opaque-plastic film 203 comprises a first opaque plastic-film surface 204 that has a surface roughness as described above.

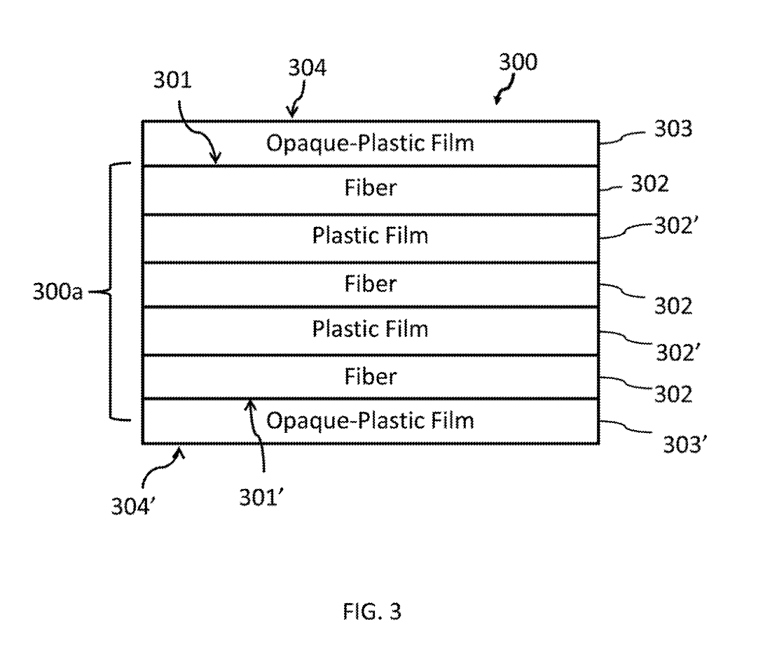

FIG. 3 is an illustration of an example of a composite material 300. The composite material 300 comprises a multilayered substrate 300a that is comprised of at least one fiber 302, and at least one plastic film 302′. In the example of FIG. 3, multiple alternating fibers 302 and plastic films 302′ are provided as shown. The uppermost fiber 302 comprises a first fiber surface 301, onto which an opaque-plastic film 303 is positioned. The opaque-plastic film 303 comprises a first opaque plastic-film surface 304 that has a surface roughness as described above. Similarly, the composite material 300 further comprises a second opaque-plastic film 303′, positioned adjacent the lowermost fiber 302. Second opaque-plastic film 303′ has a second opaque plastic-film surface 304′ that also includes a surface roughness as described above.

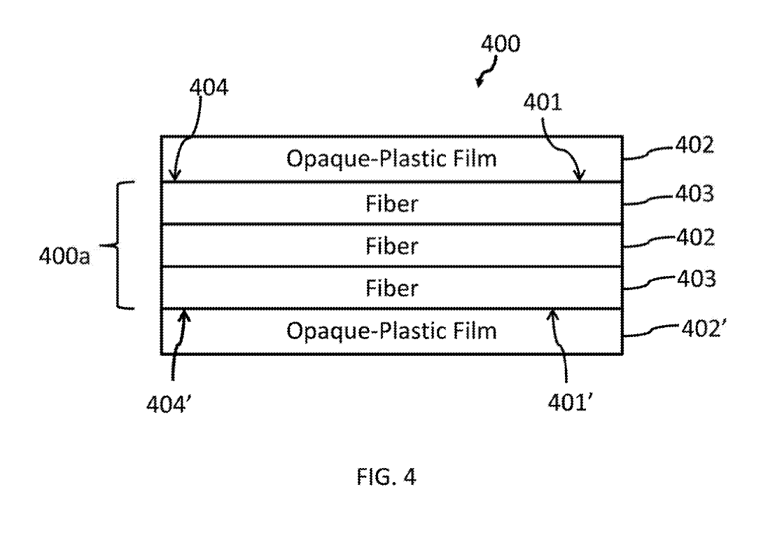

FIG. 4 is an illustration of an example of a composite material 400. The composite material 400 comprises a substrate 400a that is comprised of at least one carbon fiber 402, and, in the example of FIG. 4, multiple fibers 402 ad 403 stacked to form a multilayered substrate.

The uppermost and lower most fibers 403 comprises first and second fiber surfaces 401 and 401′ onto which opaque-plastic films 402, 402′ as described above are positioned.

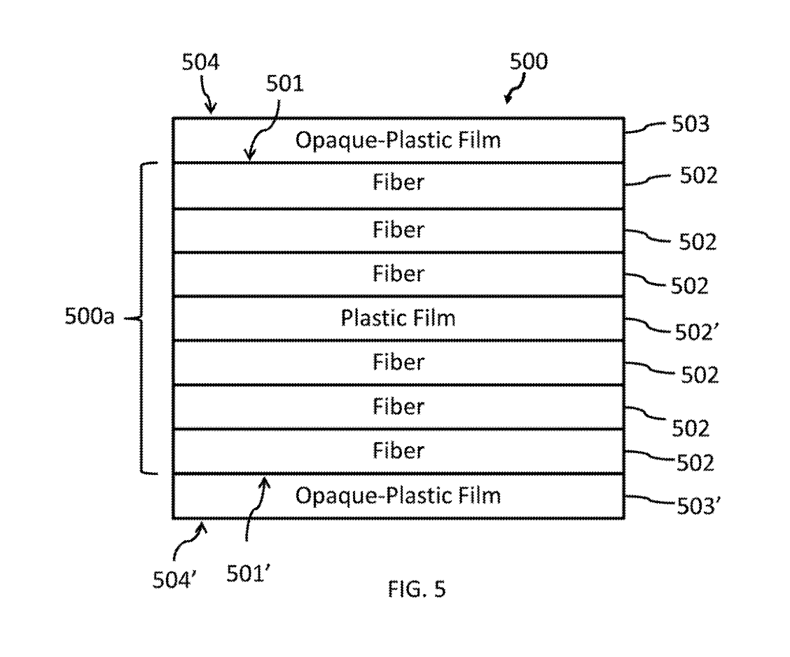

Similarly, FIG. 5 illustrates an example of a composite material 500. The composite material comprises a substrate 500a, that is comprised of at least one (and in the example of FIG. 5, multiple) fibers 502. A plastic film 502′ is provided among the various fibers 502 to form a multilayered substrate 500a. As described above, opaque-plastic films 503 and 503′ are positioned adjacent the uppermost and lowermost fibers 502 of the substrate as shown.

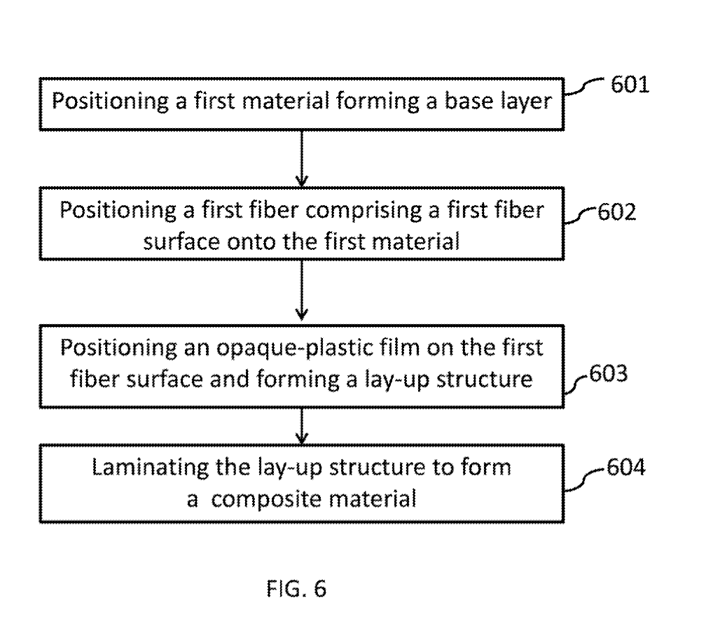

The composite materials described herein and illustrated in FIGS. 1-5 may be made by the method illustrated in FIG. 6. At 601, a first material is positioned for example by hand, or by a tape-laying machine and a laying roller as a base of a lay-up or stacked structure. The first material may include an opaque-plastic film that has a transmittance of incident light of between 10% and 90%, a plastic film that has a transmittance of incident light that is less than 10%, or a fiber (.g., glass fiber or carbon fiber). A first fiber (which may be the same material as, or different to the first material positioned at 601) is then positioned onto the first material at 602. The first fiber may comprise a fiber tape that includes glass, carbon, or combinations thereof. The first fiber may be positioned on the first material for example by hand, or by a tape-laying machine and a laying roller, wherein the tape laying device may be fed the first material, followed by the first fiber and so on to form the stacked lay-up structure as described above. The first fiber may also be pre-impregnated with polymers as described above.

Process 602 may be repeated as desired, wherein a second fiber comprising the same or a different material to the first fiber may be positioned on the first fiber. Further, the first and the second fibers may be separated by a plastic film. Positioning discrete layers of fibers and plastic films may be repeated to form a multilayered substrate.

At 603, the last layer of the substrate to be positioned comprises a fiber that includes a fiber surface onto which an opaque-plastic film is positioned to form a lay-up or stacked structure. The lay-up structure then may be laminated at 604 to form a composite material. A temperature range of 150° C. to 300° C. for 1 to 60 minutes may be used for the lamination process. Alternative lamination time periods include 5 to 30 minutes or 10 to 15 minutes.

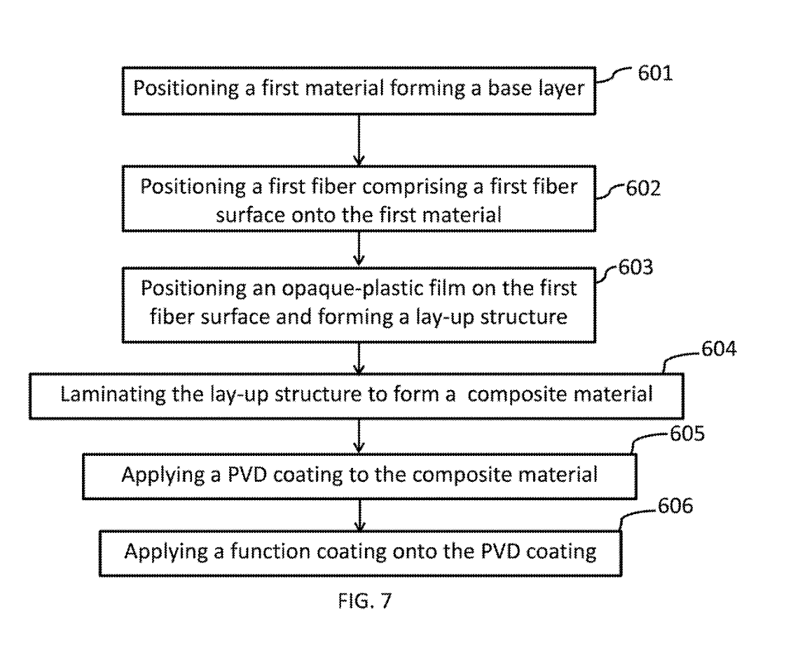

FIG. 7 provides another example method for forming the composite materials described herein and illustrated in FIG. 1-5. The example of FIG. 7 includes operations 601-604 from FIG. 6 and thus the description of those operations is not repeated here. At 605, the method further includes applying a PVD coating to the composite material from operation 604. At 606, the method then includes applying a functional coating (e.g., paint) onto the PVD coating.

As described above, a first material is positioned as the base of a lay-up or stacked structure, 701. The first material may be: an first opaque-plastic film that has a transmittance of incident light of between 10% and 90%, a plastic film that has a transmittance of incident light that is less than 10%, or a fiber comprising glass and or carbon, A first fiber is then positioned onto the first material at 702, the first fiber may be comprise a fiber tape, wherein the fiber tape may comprise glass, carbon, or combinations thereof. The first fiber may also be pre-impregnated with polymers as described above. Process 702 may be repeated, wherein a second fiber comprising the same or a different material to the first fiber may be positioned. Further, the first and the second fiber may be separated by a plastic film that is positioned between the first and the second fiber. Positioning discrete layers of fibers and plastic films may be repeated to form a multilayered substrate. In the examples described above, the last layer of the substrate to be positioned comprises a fiber comprising a first (or a second) fiber surface, onto which an opaque-plastic film is then positioned to form a lay-up or stacked structure at 703.

The lay-up structure is then laminated at a temperature range of 150° C. to 300° C. to form a composite material wherein the composite material comprises a substrate (multilayered or single layered) and an opaque-plastic-film, wherein the opaque-plastic film has a first plastic film surface that has a surface roughness of between 0.001 nm and 1 mm, In some examples the first material positioned in step 701 is also an opaque-plastic film, and on laminating will comprise the second opaque-plastic film surface of the composite material. The second plastic0film surface also comprises a surface roughness of 0.001 nm to 1 mm. The first or the second opaque-plastic film may be 0.001 μm to 1 mm thick, 0.001 mm to 0.5 mm thick, and in the range of 0.001 mm to 0.05 mm thick. In some examples the thickness of the first opaque-plastic film is the same as the thickness of the second opaque-plastic film, in anther examples the thickness of each film is different.

The composite material is then subjected to further processing, such as compression molding 705, and wherein the composite material maintains a surface that is smooth, defect free. The molded composite material may then be painted 706, or coated for example by PVD. Further functional coatings may be applied such as anti-fingerprint coatings, anti-bacterial coatings, anti-smudge coatings, tactile or soft touch and non-rigid elastomeric surfaces. Hardcoatings may also be applied to the compression molded and PVD coated composite material, wherein such composite materials may have a hardness (pencil hardness) of greater that 3 H. Such composite materials described herein also are suitable for applying metallic finishes that create a metallic luster, Composite materials produced and processed by the methods described herein, may be applied to batch to batch and roll to roll production.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

What is claimed is:

1. A composite material comprising;
a substrate comprising a fiber, and a first fiber surface; and
an opaque-plastic film positioned on said first fiber surface;
wherein said opaque-plastic film comprises a first opaque-plastic film surface that comprises a surface roughness of between 0.001 nm and 1 mm

2. The composite material of claim 1, further comprising a thin physical vapor deposition (PVD) coating positioned onto said opaque-plastic film.

3. The composite material of claim 1, wherein said opaque-plastic film comprises a transmittance of 10% to 90%.

4. The composite material of claim 1, wherein said fiber comprise carbon, glass, or a combination thereof.

5. The composite material of claim 1, wherein said substrate further comprises a plastic layer, wherein said plastic layer is selected from: a thermoset plastic, a thermoplastic, or a combination thereof.

6. The composition of claim 1, wherein, said fiber is preimpregnated with a polymer comprising polycarbonate and acrylonitrile butadiene styrene (PC-ABS).

7. The composite material of claim 1, wherein said opaque-plastic film comprises acrylonitrile butadiene styrene (ABS), polycarbonate, polybutylene (PB), poly vinylidene fluoride (PVDF), polyacrylate, polyether ether ketone (PEEK), polycarbonate and acrylonitrile butadiene styrene (PC/ABS), polyamide, poly(p-phenylene sulfide (PPS); or combinations thereof.

8. The composite material of claim 7, wherein said opaque-plastic film is about 0.001 nm to 1 mm thick.

9. The composite material of claim 1, wherein said material has a flexural modulus in the range of 0.5 Gpa to 12 Gpa.

10. A method of making a composite material comprising;
positioning an first material to form a base layer;
positioning a first fiber comprising a first fiber surface onto the first material;
positioning an opaque-plastic film onto the first fiber surface to form a lay-up structure, and
laminating the lay-up structure to form a composite material, wherein the composite material comprises a surface roughness of between 0.001 nm and 1 mm.

11. The method of claim 10, further comprising applying a PVD coating to the composite material.

12. The method of claim 11, further comprising applying a functional coating onto the PVD coating.

13. The method of claim 10, wherein said first material is a plastic film or a fiber.

14. The method of claim 11, wherein laminating is at a temperature of 150 to 300° C, for 10 to 15 minutes.

15. A composite material comprising:
a substrate comprising a first material, a first fiber, a plastic film, and a second fiber comprising a second fiber surface; and
an opaque-plastic film positioned on said second fiber surface, wherein the opaque-plastic film comprises a transmittance of 10% to 90%, and a firstopaque plastic-film surface that comprises a surface roughness of between 0.001 nm and 1 mm.
